(19) United States
(12) Patent Application Publication
(10) Pub. No.: US 2002/0158668 A1
(43) Pub. Date: Oct. 31, 2002

(54) CMOS bus pulsing

(76) Inventors: James W. Tschanz, Hillsboro, OR (US); Yibin Ye, Portland, OR (US); Vivek K. De, Beaverton, OR (US)

Correspondence Address: FISH & RICHARDSON, PC, 4350 LA JOLLA VILLAGE DRIVE, SUITE 500, SAN DIEGO, CA, 92122, US

(21) Appl. No.: 09/846,514

(22) Filed: Apr. 30, 2001

(51) Int. Cl. H03K 19/00

(52) U.S. Cl. 326/93

(57) ABSTRACT

A method and apparatus for transmitting data through a CMOS bus line includes a pulse generator to generate a pulse representing a data signal, and a decoder for receiving the pulse and an output port for delivering the detected signal to a receiving device.

### TECHNICAL FIELD

This invention relates to CMOS bus pulsing.

### BACKGROUND

CMOS logic buses are generally configured as static or dynamic buses. Static buses consume less power than dynamic buses, because a static CMOS bus consumes power only when data signals are switched and transmitted. The coupling capacitance between CMOS bus lines limits the transmission speed of a static CMOS bus. For example, when one CMOS bus line is switched in the opposite direction from two adjacent bus lines, the coupling capacitance from the first line to each adjacent line is twice as large as the inter-line capacitance, i.e., a coupling factor of two.

Dynamic CMOS buses generally operate at higher speed but consume more power than static CMOS buses. A dynamic CMOS bus operates by pre-charging a bus line to a voltage level and then conditionally discharging the line based on the data input level. Because the dynamic bus lines are always evaluated in the same direction (either high-to-low or low-to-high), the worst coupling capacitance, and therefore the worst delay, occurs when one line switches and the two adjacent lines remain at the pre-charge level. The resulting worst case coupling capacitance of a dynamic CMOS bus line to each adjacent line is equal to the inter-line capacitance, i.e., a coupling factor of one. This lower coupling capacitance allows a dynamic bus to operate faster than a static bus. However, the power consumption of a dynamic CMOS bus is higher than the static CMOS bus due to the power dissipated during the pre-charging and conditional discharging of the dynamic bus lines.

### DESCRIPTION OF DRAWINGS

FIG. 1 is a schematic representation of a static CMOS logic bus line;

FIG. 2 is a schematic representation of an embodiment of the invention;

FIG. 3 is a schematic representation of a pulse generator circuit;

FIG. 4 is a timing diagram for the pulse generator circuit of FIG. 3.

FIG. 5 is a timing diagram for the embodiment of FIG. 2.

### DETAILED DESCRIPTION

Referring to FIG. 1, a static CMOS logic bus line 100 includes a CLK signal 106, a data signal D 150, a flip-flop 130, a data signal output D160, a series of repeaters 110A-110N, and a receiving flip-flop 140. The CMOS logic bus 100 also includes a series of resistor-capacitor (RC) loads 120A-120C, which represent the load imposed by the interconnections between adjacent repeaters 110A-110N.

Repeaters 110A-110N are included in CMOS logic bus line 100 in order to regenerate the data signal D 160 as it is transmitted through the RC loads 120A-120C. The number of repeaters 110A-110N included in CMOS logic bus line 100 is determined by the overall length of the bus and the resulting total RC load. In operation, data signal D150 (which may be at a high or low voltage) is delivered as D160 from flip-flop 130 when CLK 106 goes high, causing the D160 signal to be transmitted through repeaters 110A-110N, and to the input 142 of receiving flip-flop 140 (also enabled by CLK 106). The period of CLK 106 is set so that D160 has sufficient time to propagate through repeaters 110A-110N and to the input 142 of receiving flip-flop 140, at which time the next rising edge of CLK 106 causes the D160 signal to be latched by flip-flop 140.

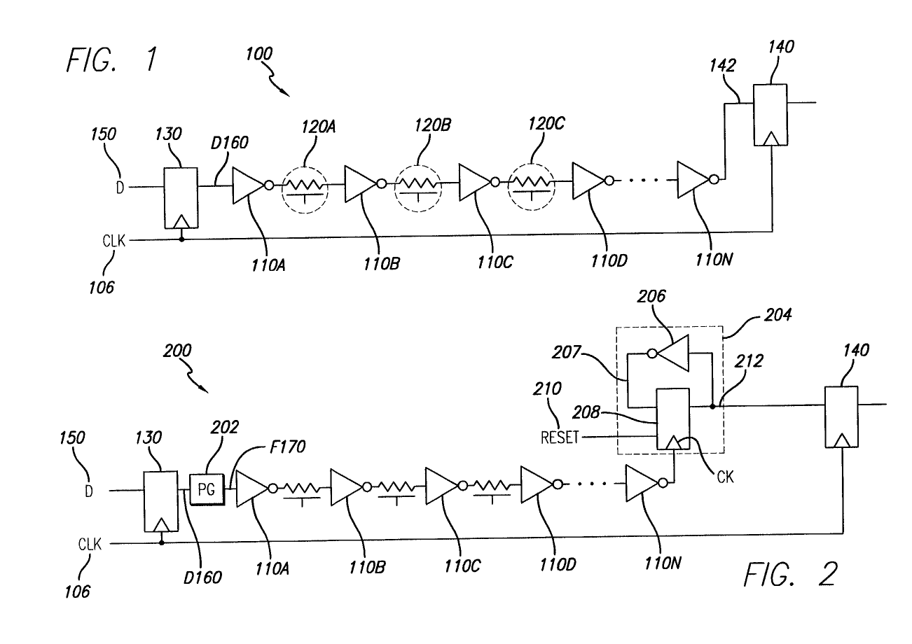

Referring to FIG. 2, in an embodiment according to the invention, a pulse skewed CMOS logic (PSCL) bus line 200 is shown. PSCL bus line 200 differs from the static CMOS bus line 100 by the inclusion of pulse generator 202 and decoder 204. The data to be sent on the bus line is received by the pulse generator and converted to pulses that are decoded at the other end of the line in decoder 204. The PSCL bus line 100 operates by generating a pulse, F170, for each incoming edge of data, D160.

All of the pulses, F170, are generated in the same direction (either positive or negative) and transmitted through the bus line to decoder 204. Because all pulses, F170, are generated in the same direction, the worst coupling factor between PSCL bus lines is one, which reduces the total line capacitance which must be driven by repeaters 110A-110N and allows the PSCL bus line to operate much faster than the static bus line 100. Furthermore, the PSCL pulses, F170, are generated only when the data signal D160 makes a transition. Therefore, power is dissipated in the PSCL bus line 200 only when pulses are being transmitted.

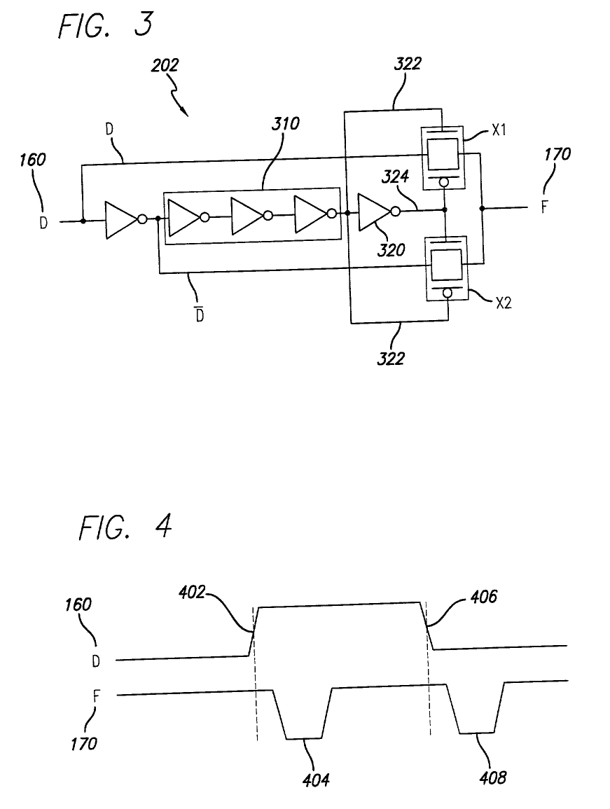

Referring to FIGS. 3 and 4 an exemplary pulse generator circuit 202 receives data signal D 160, delivers output signal F 170, and includes transmission gates X1 and X2, and delay block 310. Transmission gates X1 and X2, inverter 320, inputs 322 and output 324 are configured to produce an XOR negative-going pulse for each edge of D160. For example, pulses 404 and 408 are generated in response to the rising and falling edges 402 and 406, respectively, of data signal D 160, as shown in FIG. 4. The width of each pulse generated by pulse generator 202 is controlled by the number of inverters included in delay block 310.

Circuit 202 is just one example of a pulse generator circuit, any circuit which produces a pulse for each edge of data signal D 160 could be used. Alternatively, a positive-going pulse generator circuit could be used.

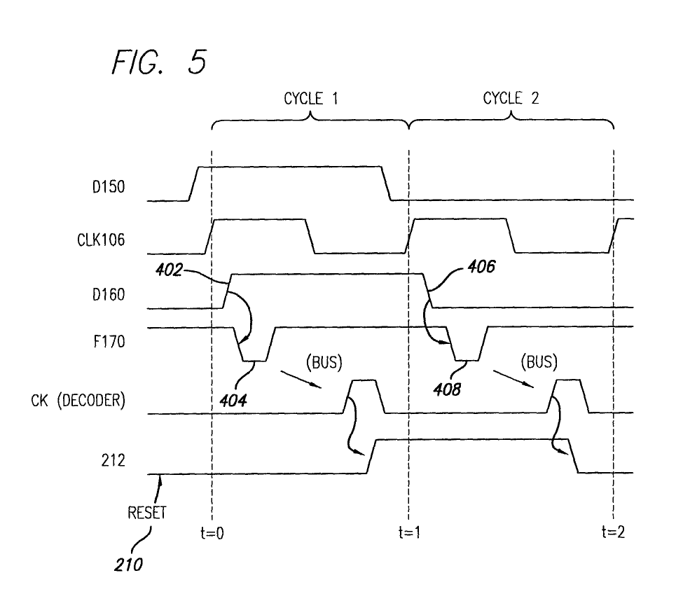

Referring to FIGS. 2 and 5, PSCL bus line 200 includes a decoder 204 to detect the transmission of pulse F170 through PSCL bus line 200. Decoder 204 is configured as a ‘toggle’ flip-flip, in which the output 212 is connected to the input 207 through inverter 206, such that each pulse F170 will cause output 212 and input 207 to change voltage level.

In operation, when CMOS PSCL bus line 200 is powered on, RESET 210 is input to decoder 204, resetting flip-flop 208 to a known state, in this case resetting output 212 to ‘0’, and inverting input 207 to ‘1’. At the beginning of cycle 1, signal D 150 has just completed a ‘0’-to-‘1’ transition, CLK 106 goes to ‘1’ at t=0, which causes D160 to be output from latch 130 and input to pulse generator 202. Rising edge 402 of D160 causes pulse generator 202 to produce a pulse 404 at output F170 which is transmitted through repeaters 110A-110N.

At the receiving end, transmitted pulse 404 is then delivered to the ‘CK’ input of flip-flop 208, which causes the ‘1’ at input 207 to be latched through to output 212 and delivered to receiving flip-flop 140. Pulse 404 also toggles the flip-flop 208 input 207 to a ‘0’. The next rising edge of CLK 106, at t=1, latches through the ‘1’ at input 212 of receiving flip-flop 140 to the output of flip-flop 140. The timing in cycle 2, when D150 has just completed a 1-to-0 transition, is similar to the timing of cycle 1, except that the rising edge of CLK 106 at t=2 latches a ‘0’ at the output of receiving flip-flop 140.

Thus, the successive pulses F 170 indicate the start and end of the data signal, and the decoder decodes the successive pulses to recover the data signal.

Decoder 204 circuit, as shown in FIG. 2, is one example of a decoder circuit. Other decoder circuits which can detect pulses could be used. In particular, a PSCL bus which uses positive-going pulses would require a decoder to be reset to ‘1’ at power on, and detect positive-going pulses being transmitted.

Another advantage of the PSCL bus is that the repeaters can be “skewed” in favor of the “evaluate” transition. This means that the repeaters can be made to have a shorter delay time for a falling edge than for a rising edge, or vice-versa. This cannot be done with a standard CMOS bus because both the rising and the falling edges are transmitted by the repeaters, and so each one is equally important. However for the PSCL bus (as well as for dynamic busses), the bus lines are always evaluated in the same direction, which means the repeaters can be skewed. By skewing the repeaters, the PSCL bus can be made faster.

Other embodiments are within the scope of the following claims.

What is claimed is:

1. An apparatus comprising:
a pulse generator to generate a pulse representing a data signal, the pulse generator having
an input port for receiving the data signal,
an output port to deliver the pulse through a CMOS bus line to a decoder,
the decoder having
an input port for receiving the pulse, and
an output port for delivering a detected signal to a receiving device.

2. The apparatus of claim 1 in which the pulse generator is configured to generate a pulse based on a rising or falling edge of the data signal.

3. The apparatus of claim 1 in which the pulse generator is configured to generate a pulse based on a high or low voltage level of the data signal.

4. The apparatus of claim 1 in which the pulse generator is configured to generate a negative-going pulse based on a rising or falling edge of the data signal.

5. The apparatus of claim 1 in which the pulse generator is configured to generate a positive-going pulse based on a rising or falling edge of the data signal.

6. The apparatus of claim 1 in which the pulse generator further comprises a delay block to govern a width of the pulse.

7. The apparatus of claim 6 in which the delay block comprises one or more inverters.

8. The apparatus of claim 6 in which the pulse generator further comprises an XOR gate to produce a negative-going pulse on a rising edge or falling edge of the data signal.

9. The apparatus of claim 1 in which the decoder comprises a toggle flip-flop that uses the pulse to change the detected signal output to the receiving device.

10. The apparatus of claim 9 in which the decoder comprises a reset line to receive a reset signal to put the detected signal output at a known voltage level.

11. The apparatus of claim 9 in which the decoder uses a negative-going pulse to toggle the output to the receiving device.

12. The apparatus of claim 9 in which the decoder uses a positive-going pulse to toggle the output to the receiving device.

13. The apparatus of claim 1 further comprising:
a first flip-flop having
an input to receive a data signal,
a clock input to determine when to latch the data signal,
an output port to deliver the data signal to the pulse generator,
a second flip-flop having
an input port to receive the detected signal from the decoder,
a clock input to determine when to latch the decoder output,
an output port to deliver the latched signal to a target circuit, and
a clock signal to govern the latching of the first flip-flop and the second flip-flop.

14. The apparatus of claim 13 wherein the clock signal duration is sufficiently long to allow the pulse to be delivered to the input of the second flip-flop before latching the second flip-flop.

15. A method comprising:
receiving data signals each of which comprises a high or low signal that spans a period between rising and falling signal edges,
converting each of the data signals into a pair of pulses that correspond to the signal edges of the data signal, all of the pulses for all of the data signals being either high or low pulses,
applying the pulses to one end of a static bus, and at the other end of the static bus,
recovering the data signals based on the pulses.

16. The method of claim 15 wherein converting each of the data signals into a pair of pulses further comprises:
detecting a signal edge change of the data signal, and
adjusting a width of the pulses with a delay element.

17. The method of claim 15 wherein recovering the data signals based on the pulses further comprises:
decoding the pulses, and
outputting a signal to a receiving device to indicate that a data signal was received.

18. The method of claim 17 wherein decoding the pulses further comprises:
toggling the output of a flip-flop.

19. The method of claim 18 wherein toggling the output of a flip-flop further comprises:
resetting the flip-flop to a known state before data signals are applied to the static bus.

20. An apparatus comprising:
an output port to deliver a pulse through a CMOS bus line to a decoder,
the decoder having
an input port for receiving the pulse, and
an output port for delivering a detected signal to a receiving device.

21. The apparatus of claim 20 in which the decoder comprises a toggle flip-flop that uses the pulse to change the detected signal output to the receiving device.

22. The apparatus of claim 20 in which the decoder comprises a reset line to receive a reset signal to put the detected signal output at a known voltage level.

23. The apparatus of claim 20 in which the decoder uses a negative-going pulse to toggle the output to the receiving device.

24. The apparatus of claim 20 in which the decoder uses a positive-going pulse to toggle the output to the receiving device.

25. The apparatus of claim 20 further comprising:
a flip-flop having
an input port to receive the detected signal from the decoder,
a clock input to determine when to latch the decoder output,
an output port to deliver the latched signal to a target circuit, and
a clock signal to govern the latching of the first flip-flop and the second flip-flop.

26. An apparatus comprising:
a pulse generator to generate a pulse representing a data signal, the pulse generator having
an input port for receiving the data signal,
an output port to deliver the pulse through a CMOS bus line.

27. The apparatus of claim 26 in which the pulse generator is configured to generate a pulse based on a rising or falling edge of the data signal.

28. The apparatus of claim 26 in which the pulse generator is configured to generate a pulse based on a high or low voltage level of the data signal.

29 The apparatus of claim 26 in which the pulse generator is configured to generate a negative-going pulse based on a rising or falling edge of the data signal.

30. The apparatus of claim 26 in which the pulse generator is configured to generate a positive-going pulse based on a rising or falling edge of the data signal.

31. The apparatus of claim 26 in which the pulse generator further comprises a delay block to govern a width of the pulse.

32. The apparatus of claim 31 in which the delay block comprises one or more inverters.

33. The apparatus of claim 32 in which the pulse generator further comprises an XOR gate to produce a negative-going pulse on a rising edge or falling edge of the data signal.
